(19) United States
(12) Patent Application Publication
(10) Pub. No.: US 2008/0259535 A1
(43) Pub. Date: Oct. 23, 2008

(54) SLIDING OPEN/CLOSED DEVICE

(76) Inventors: Chih-Wei Wu, Taipei City (TW); Jiung-Cheng Pan, Tai-Nan City (TW); Shr-Ching Lo, Hualien County (TW)

Correspondence Address: NORTH AMERICA INTELLECTUAL PROPERTY CORPORATION, P.O. BOX 506, MERRIFIELD, VA, 22116, US

(21) Appl. No.: 11/957,477

(22) Filed: Dec. 16, 2007

(30) Foreign Application Priority Data
Apr. 19, 2007 (TW) 096113808

(51) Int. Cl. H05K 7/00

(52) U.S. Cl. 361/679

(57) ABSTRACT

A sliding open/closed device includes a first module and a second module. When the first module is closed with the second module, a first magnetic component disposed inside the first module is attracted by a second magnetic component disposed inside the second module. When a sliding component disposed inside the first module is located at a second position, the first magnetic component is attracted by the second magnetic component and is repelled by a third magnetic component disposed inside the second module so that the first module can be closed with the second module.

### BACKGROUND OF THE INVENTION

1. Field of the Invention

The present invention relates to an open/closed device, and more specifically, to a sliding open/closed device.

2. Description of the Prior Art

With improvement of communication and electronic techniques, portable communication devices have become indispensable electronic products in daily life. A mobile phone is a most representative example. Along with the all-in-one trend, there are more and more additional functions installed in mobile phones. For a user, it is more and more difficult to use a mobile phone correctly. Therefore, how to let a user operate a mobile phone easily and conveniently is a concern in mechanical design of the mobile phone. A sliding-type mobile phone is a solution to the said problem.

A traditional sliding-type mobile phone utilizes a curved elastic sheet for providing elastic force as a driving force for expanding or closing its upper and lower cases. If a user wants to use a sliding-type mobile phone, the user just needs to push the upper case of the sliding-type mobile phone up to an inverse deformation point of the curved elastic sheet. Subsequently, the upper case keeps moving due to an elastic force generated during the deformation of the elastic sheet until the sliding-type mobile phone is expanded completely. Similarly, if the user wants to close the expanded sliding-type mobile phone, the user just needs to pull the upper case down to the inverse deformation point of the curved elastic sheet. Subsequently, the upper case keeps moving due to an inverse elastic force generated by the elastic sheet until the upper case of the sliding-type mobile phone is closed with the lower case. However, the upper case and the lower case are not located in the same plane when the sliding-type mobile phone is expanded completely. Thus, in this situation, it is not only less convenient for the user to operate the sliding-type mobile phone, but also less flexible in mechanical design of the sliding-type mobile phone.

### SUMMARY OF THE INVENTION

The present invention provides a sliding open/closed device comprising a first module and a second module. The first module comprises a first base, a sliding component connected to the first base, the first base having a protruding portion, and a first magnetic component disposed at a first end of the first base. The second module is connected to the first module. The second module comprises a second base having a slot, the sliding component being installed movably inside the slot, a side lid disposed at a side of the second base, the side lid having a first track and a second track, the protruding portion being movable in the first track and the second track, a first elastic sheet installed in the second track for constraining the protruding portion in a first direction when the sliding component is located at a first position, a second elastic sheet installed in the second track for constraining the protruding portion in a second direction when the sliding component is located at a second position, a second magnetic component connected to a first end of the second base and disposed at a position corresponding to the first magnetic component, and a third magnetic component connected to a second end of the second base, wherein the first magnetic component disposed inside the first module is attracted by the second magnetic component disposed inside the second module when the first module is closed with the second module, and the first magnetic component is attracted by the second magnetic component and is repelled by the third magnetic component disposed inside the second module so that the first module can be closed with the second module when the sliding component disposed inside the first module is located at the second position.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an exploded diagram of a sliding open/closed device according to the present invention.

FIG. 2 is an enlarged diagram of the first elastic sheet and the second elastic sheet in FIG. 1.

FIG. 3 is an assembly diagram of the first base and the second base in FIG. 1.

FIG. 4 is a side diagram of the sliding open/closed device in FIG. 1 when the first module is closed with the second module.

FIG. 5 is an expanded side-diagram of the sliding open/closed device in FIG. 4.

FIG. 6 is a side diagram of the sliding component in FIG. 1 being located at the first position.

FIG. 7 is a sectional diagram of the sliding component in FIG. 1 being located at the first position.

FIG. 8 is a side diagram of the sliding component in FIG. 1 being located at the second position.

FIG. 9 is a sectional diagram of the sliding component in FIG. 1 being located at the second position.

### DETAILED DESCRIPTION

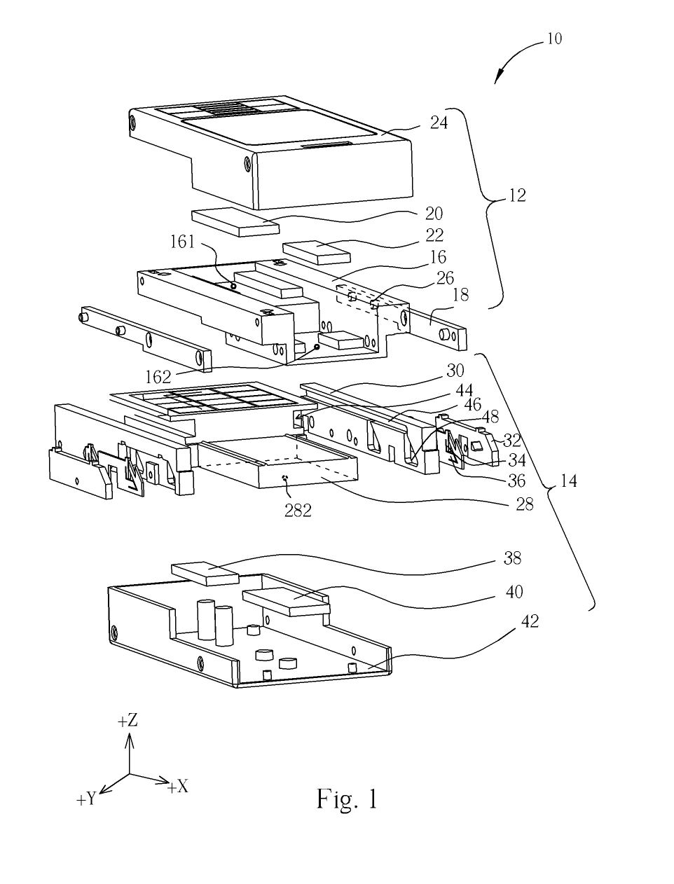

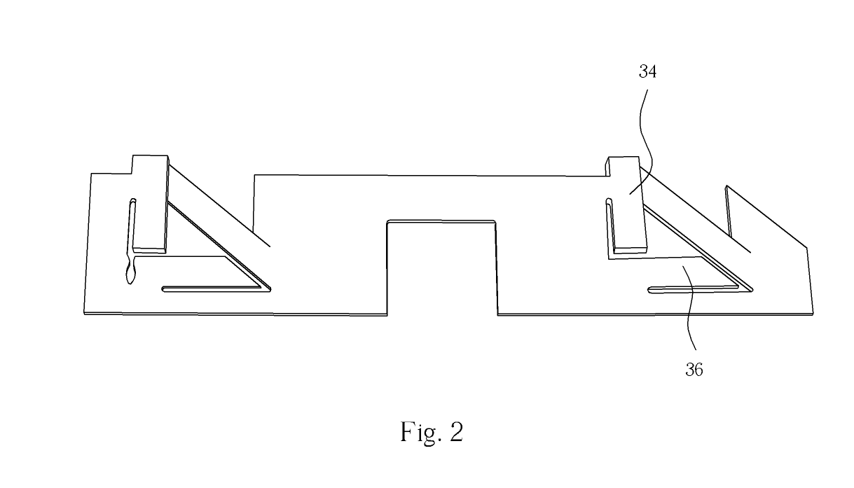

First, please refer to FIG. 1. FIG. 1 is an exploded diagram of a sliding open/closed device 10 according to the present invention. The sliding open/closed device 10 comprises a first module 12 and a second module 14. The second module 14 is connected to the first module 12. A side of the first module 12 has a first base 16, a sliding component 18, a first magnetic component 20, a fourth magnetic component 22, and an upper covering 24. The sliding component 18 is connected to the first base 16. The sliding component 18 has a protruding portion 26. The protruding portion 26 can be a pillar. The first magnetic component 20 is disposed at a first end 161 of the first base 16. The fourth magnetic component 22 is disposed at a second end 162 of the first base 16. The upper covering 24 is utilized for covering the first base 16, the sliding component 18, the first magnetic component 20 and the fourth magnetic component 22. A side of the second module 14 corresponding to the said side of the first module 12 has a second base 28, a side lid 30, a fixed plate 32, a first elastic sheet 34, a second elastic sheet 36, a second magnetic component 38, a third magnetic component 40, and a lower covering 42. The second base 28 has a slot 44. The sliding component 18 is installed movably inside the slot 44. The side lid 30 has a first track 46 and a second track 48. The first track 46 is connected to the second track 48. The side lid 30 is installed at a side of the first base 16. The first track 46 is utilized for guiding the protruding portion 26 to move in the X-axis direction. The fixed plate 32 is installed at a side of the side lid 30 for forming the second track 48 (a right-triangle track shown in FIG. 1) together with the side lid 30 to guide the protruding portion 26 to move in the X-axis direction, the Z-axis direction, or any combination of the two directions. Next, please refer to FIG. 1 and FIG. 2 at the same time. FIG. 2 is an enlarged diagram of the first elastic sheet 34 and the second elastic sheet 36 in FIG. 1. The first elastic sheet 34 is installed inside the second track 48 for constraining the protruding portion 26 in the +Z-axis direction when the sliding component 18 is pushed to a first position. The second elastic sheet 36 is installed inside the second track 48 for constraining the protruding portion 26 in the X-axis direction when the sliding component 18 is pushed to a second position. Furthermore, the first elastic sheet 34 and the second elastic sheet 36 can be made of metal material, and as shown in FIG. 1, the first elastic sheet 34 is preferably connected to the second elastic sheet 36 to create a monolithic structure. The second magnetic component 38 is disposed at a first end 281 of the second base 28 (not shown in FIG. 1). The third magnetic component 40 is disposed at a second end 282 of the second base 28. The lower covering 42 is utilized for covering the second base 28, the side lid 30, the fixed plate 32, the first elastic sheet 34, the second elastic sheet 36, the second magnetic component 38 and the third magnetic component 40. The said sliding open/closed device 10 can be a wireless communication device, such as a mobile phone. The first magnetic component 20, the second magnetic component 38, the third magnetic component 40, and the fourth magnetic component 22 can be magnets. Furthermore, the fourth magnetic component 22 can be an optional component.

It should be mentioned that the combination of the side lid 30 and the fixed plate 32, the combination of the first base 16 and the sliding component 18, the combination of the second base 28 and the side lid 30 can be achieved in a screw-locking manner. Combination methods mentioned in the embodiment of the present invention are not limited to the said method. Furthermore, the side lid 30, the fixed plate 32, the first elastic sheet 34, and the second elastic sheet 36 can be formed integrally to save the cost and simplify the assembly process.

More detailed description for the sliding open/closed device 10 is provided as follows. The number of the protruding portion, the track, and the elastic sheet is not limited to one. As shown in FIG. 1, the number of the protruding portion 26, the second track 48, the first elastic sheet 34, and the second elastic sheet 36 can all increase up to two so as to make the first module 12 and the second module 14 move more smoothly and steadily. In a same manner, another side of the first module 12 and another side of the second module 14 can also have the same structures as mentioned above to make the first module 12 and the second module 14 move more smoothly and steadily.

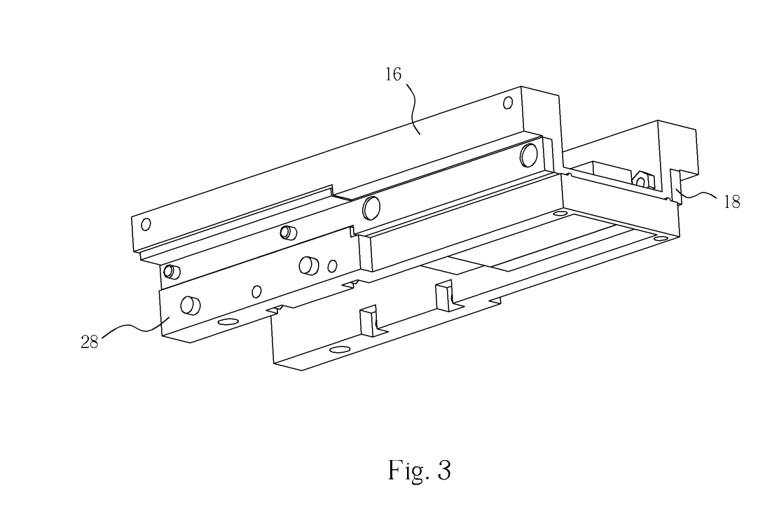

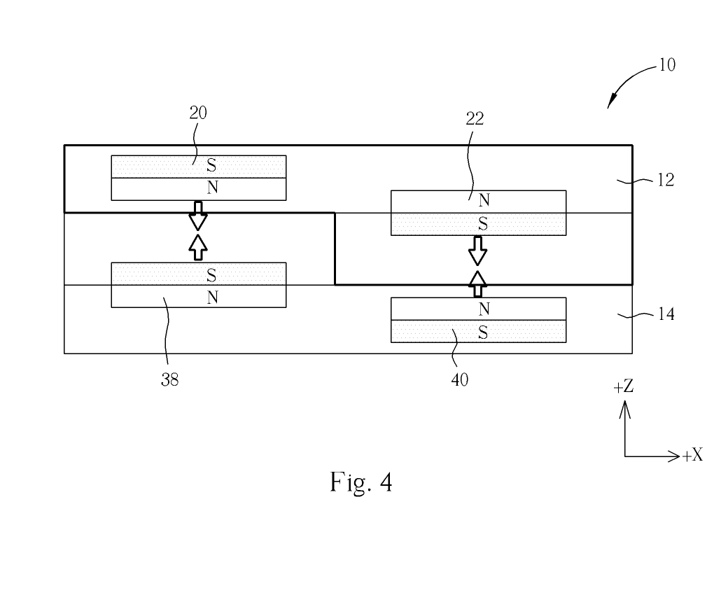

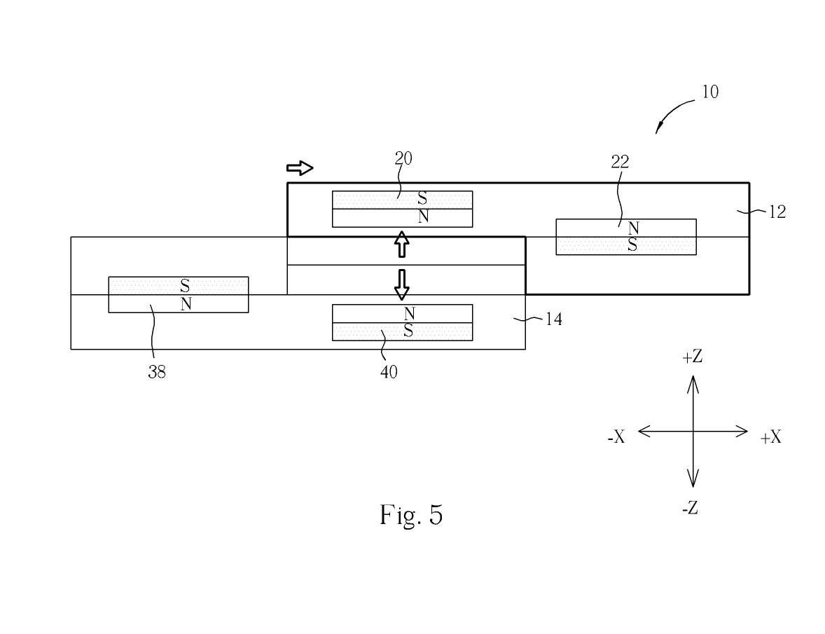

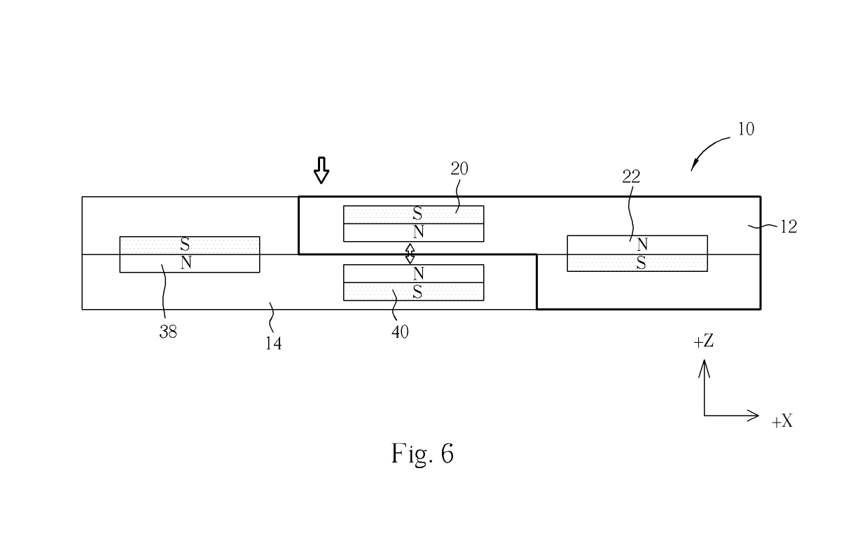

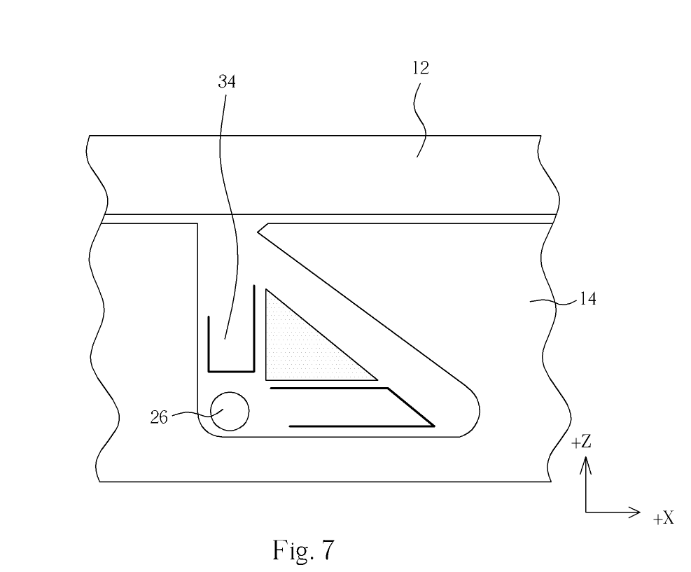

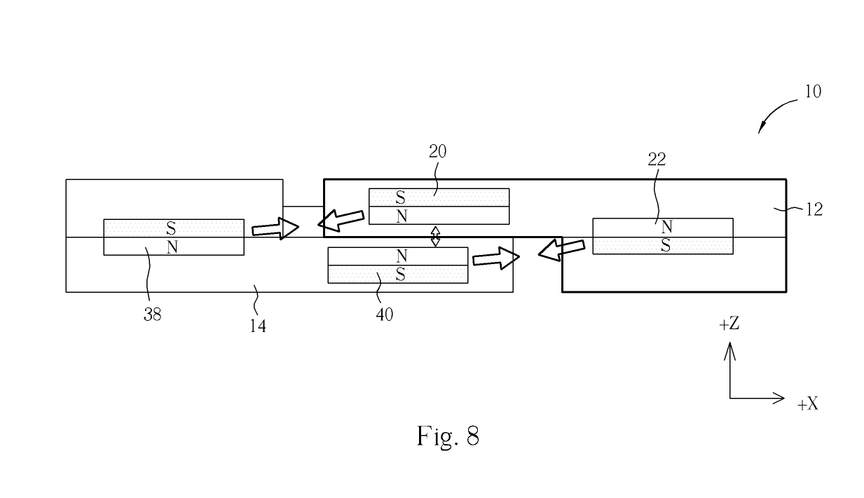

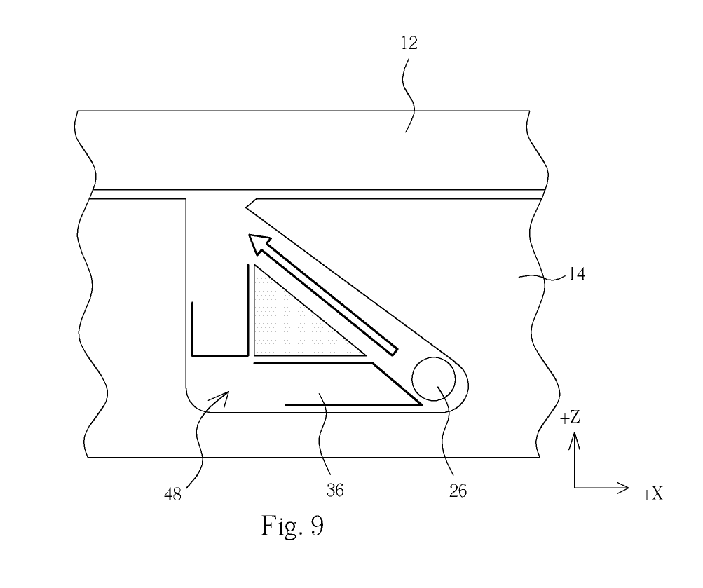

Please refer to FIG. 1 and FIG. 3 at the same time. FIG. 3 is an assembly diagram of the first base 16 and the second base 28 in FIG. 1. As shown in FIG. 3, the sliding component 18 can be installed movably in the slot 44 shown in FIG. 1 so as to make the first base 16 be closed with the second base 28, and other components shown in FIG. 1 are installed on the first base 16 and the second base 28 in turn as mentioned above. Please refer to FIG. 4. FIG. 4 is a side diagram of the sliding open/closed device 10 in FIG. 1 when the first module 12 is closed with the second module 14. As shown in FIG. 4, when the first module 12 is closed with the second module 14, the first magnetic component 20 (upper part is S pole, and lower part is N pole) and the second magnetic component 38 (upper part is S pole, and lower part is N pole) are attracted by each other. In a same manner, the fourth magnetic component 22 (upper part is N pole, and lower part is S pole) and the third magnetic component 40 (upper part is N pole, and lower part is S pole) are also attracted by each other. Thus, the first module 12 is closed tightly with the second module 14 by magnetic attractions among the said magnetic components. Please refer to FIG. 1 and FIG. 5 at the same time. FIG. 5 is an expanded side-diagram of the sliding open/closed device 10 in FIG. 4. When the user wants to use the sliding open/closed device 10, the user just needs to exert force on the first module 12 in the X-axis direction so as to make the protruding portion 26 of the sliding component 18 move along the first track 46 until the first module 12 reaches a position shown in FIG. 4. At this moment, a magnetic repulsion appears between the first magnetic component 20 and the third magnetic component 40 due to N polar repulsions. Therefore, the user needs to exert force in the −Z-axis direction to overcome the magnetic repulsion so that the protruding portion 26 of the sliding component 18 can be pushed to enter the second track 48 shown in FIG. 1. When moving along the Z-axis direction in the second track 48, the protruding portion 26 presses down the first elastic sheet 34 until the first module 12 reaches the first position. Once the first module 12 reaches the first position, the first elastic sheet 34 returns to the original form and then constrains the protruding portion 26 in the +Z-axis direction. Please refer to FIG. 6 and FIG. 7. FIG. 6 is a side diagram of the sliding component 18 in FIG. 1 being located at the first position. FIG. 7 is a sectional diagram of the sliding component 18 in FIG. 1 being located at the first position. As shown in FIG. 7, the protruding portion 26 is against the first elastic sheet 34 in the +Z-axis direction due to the magnetic repulsion between the first magnetic component 20 and the third magnetic component 40 (as shown in FIG. 6). Thus, the sliding open/closed device 10 can be in a steadily-expanded state. Please refer to FIG. 8 and FIG. 9. FIG. 8 is a side diagram of the sliding component 18 in FIG. 1 being located at the second position. FIG. 9 is a sectional diagram of the sliding component 18 in FIG. 1 being located at the second position. When the user wants to close the sliding open/closed device 10, the user also needs to exert force on the first module 12 in the X-axis direction to push the first module 12 to a position shown in FIG. 8. When moving along the X-axis direction in the second track 48, the protruding portion 26 presses down the second elastic sheet 36 until the first module 12 reaches the second position shown in FIG. 9. Once the first module 12 reaches the second position shown in FIG. 9, the second elastic sheet 36 returns to the original form and then constrains the protruding portion 26 in the X-axis direction. As shown in FIG. 8, there are three magnetic forces exerting on the first module 12 at this moment, which are a magnetic attraction between the first magnetic component 20 and the second magnetic component 38, a magnetic repulsion between the first magnetic component 20 and the third magnetic component 40, and a magnetic attraction between the third magnetic component 38 and the fourth magnetic component 40 respectively. Then, as shown in FIG. 9, the protruding portion 26 can only move along the hypotenuse track of the second track 48 because the second elastic sheet 36 constrains the protruding portion 26 in the X-axis direction. In such a manner, once the protruding portion 26 is pushed to the second position shown in FIG. 9, the first module 12 will move back to the position shown in FIG. 4 along the hypotenuse track of the second track 48 and the first track 46 by the magnetic attraction between the first magnetic component 20 and the second magnetic component 38, the magnetic repulsion between the first magnetic component 20 and the third magnetic component 40, and the magnetic attraction between the third magnetic component 38 and the fourth magnetic component 40.

In the said embodiment, the magnetic pole positions of the first magnetic component 20 (upper part is S pole, and lower part is N pole) and the second magnetic component 38 (upper part is S pole, and lower part is N pole) can be reversed. That is to say, the upper and lower parts of the first magnetic component 20 can be N pole and S pole respectively, and the upper and lower parts of the second magnetic component 38 can be N pole and S pole respectively. Similarly, the magnetic pole positions of the fourth magnetic component 22 (upper part is N pole, and lower part is S pole) and the third magnetic component 40 (upper part is N pole, and lower part is S pole) can also be reversed. That is to say, the upper and lower parts of the fourth magnetic component 22 can be S pole and N pole respectively, and the upper and lower parts of the third magnetic component 40 can be S pole and N pole respectively.

Compared with the prior art, the present invention utilizes magnetic forces among the magnetic components to close or expand a sliding-type mobile phone. When a user wants to use a sliding-type mobile phone of the present invention, the user just needs to push the upper case of the sliding-type mobile phone and then presses down the upper case so that the sliding-type mobile phone can be expanded into a bar mobile phone. That is to say, the upper and lower cases of the sliding-type mobile phone can be located in the same plane. Thus, it is not only more convenient for a user to operate the sliding-type mobile phone, but also more flexible in mechanical design of the sliding-type mobile phone.

Those skilled in the art will readily observe that numerous modifications and alterations of the device and method may be made while retaining the teachings of the invention.

What is claimed is:

1. A sliding open/closed device comprising:
a first module comprising:
a first base;
a sliding component connected to the first base, the first base having a protruding portion; and
a first magnetic component disposed at a first end of the first base; and
a second module connected to the first module, the second module comprising:
a second base having a slot, the sliding component being installed movably inside the slot;
a side lid disposed at a side of the second base, the side lid having a first track and a second track, the protruding portion being movable in the first track and the second track;
a first elastic sheet installed in the second track for constraining the protruding portion in a first direction when the sliding component is located at a first position;
a second elastic sheet installed in the second track for constraining the protruding portion in a second direction when the sliding component is located at a second position;
a second magnetic component connected to a first end of the second base and disposed at a position corresponding to the first magnetic component; and
a third magnetic component connected to a second end of the second base;
wherein the first magnetic component disposed inside the first module is attracted by the second magnetic component disposed inside the second module when the first module is closed with the second module, and the first magnetic component is attracted by the second magnetic component and is repelled by the third magnetic component disposed inside the second module so that the first module can be closed with the second module when the sliding component disposed inside the first module is located at the second position.

2. The sliding open/closed device of claim 1, wherein the second module further comprises a fixed plate installed at a side of the side lid for forming the second track together with the side lid to guide the protruding portion to move in the first direction and the second direction.

3. The sliding open/closed device of claim 2, wherein the side lid, the fixed plate, the first elastic sheet, and the second sheet are integrally formed.

4. The sliding open/closed device of claim 2, wherein the fixed plate is installed at a side of the side lid in a locking manner.

5. The sliding open/closed device of claim 1, wherein the first module further comprising a fourth magnetic component disposed at a second end of the first base.

6. The sliding open/closed device of claim 5, wherein the first magnetic component, the second magnetic component, the third magnetic component, and the fourth magnetic component are magnets.

7. The sliding open/closed device of claim 1, wherein the sliding component is connected to the first base in a locking manner.

8. The sliding open/closed device of claim 1, wherein the side lid is installed at a side of the second base in a locking manner.

9. The sliding open/closed device of claim 1, wherein the protruding portion is a pillar.

10. The sliding open/closed device of claim 1, wherein the second track is a right-triangle track.

11. The sliding open/closed device of claim 1, wherein the first module further comprises an upper covering for covering the first base, the sliding component, and the first magnetic component.

12. The sliding open/closed device of claim 1, wherein the second module further comprises a lower covering for covering the second base, the side lid, the first elastic sheet, the second elastic sheet, the second magnetic component, and the third magnetic component.

13. The sliding open/closed device of claim 1, wherein the first elastic sheet and the second sheet are made of metal material.

14. The sliding open/closed device of claim 1, wherein the sliding open/closed device is a wireless communication device.

15. The sliding open/closed device of claim 14, wherein the sliding open/closed device is a mobile phone.
